(19) United States
(12) Patent Application Publication
(10) Pub. No.: US 2025/0358954 A1
(43) Pub. Date: Nov. 20, 2025

(54) HEAT DISSIPATION ASSEMBLY AND MOTHERBOARD MODULE

(71) Applicant: Wiwynn Corporation, New Taipei City (TW)

(72) Inventors: Yi Cheng, New Taipei City (TW); WEN AN CHEN, New Taipei City (TW); Tsung-Han Li, New Taipei City (TW)

(21) Appl. No.: 19/084,854

(22) Filed: Mar. 20, 2025

Related U.S. Application Data
(60) Provisional application No. 63/647,650, filed on May 15, 2024.

(30) Foreign Application Priority Data
Nov. 8, 2024 (TW) 113142988

(51) Int. Cl. H05K 7/20

(52) U.S. Cl. CPC H05K 7/20263; H05K 7/20236

(57) ABSTRACT

A heat dissipation assembly is configured to be immersed in a coolant in a tank and thermally coupled to a heat source. The heat dissipation assembly includes a heat exchange plate and a boiling enhancement structure. The heat exchange plate has a heat absorption surface, a heat dissipation surface and a coupling surface. The heat absorption surface is configured to be thermally coupled to the heat source, the heat dissipation surface faces away from the heat absorption surface, the coupling surface is located at a periphery of the heat dissipation surface, and the coupling surface is configured to be connected to a cover so as to form a fluid chamber. The boiling enhancement structure is located at the heat dissipation surface of the heat exchange plate and configured to be exposed to the coolant in the tank.

### CROSS-REFERENCE TO RELATED APPLICATIONS

This non-provisional application claims priority under 35 U.S.C. § 119 (a) on Provisional Application No(s). 63/647,650 filed in U.S.A. on May 15, 2024, and Patent Application No(s). 113142988 filed in Taiwan, R.O.C. on Nov. 8, 2024, the entire contents of which are hereby incorporated by reference.

### TECHNICAL FIELD

The disclosure relates to a heat dissipation assembly and a motherboard module.

### BACKGROUND

In a case that a heat source of the motherboard is provided with an immersion-typed heat dissipation device, during the test of the motherboard (e.g., board function test), a boiler plate may be used to be thermally coupled to the heat source and is immersed in the coolant for performing the test. However, when there are some issues during the test, the coolant is required to be frequently sucked out of a tank, causing the loss of the coolant. Therefore, generally, a cold plate or a heat sink may replace the boiler plate to be thermally coupled to the heat source for performing some of the test projects in the air environment, and then the cold plate and the heat sink may be replaced by the boiler plate to be immersed in the coolant for performing other test projects, which reduce the opportunity of the loss of the coolant.

However, using the cold plate/the heat sink and boiler plate one after another for the test may increase the complexity of test since assembly and the disassembly processes are required to be performed repeatedly and are troublesome. As a result, how to solve the aforementioned issue are one of the topics in this field.

### SUMMARY

One embodiment of the disclosure provides a heat dissipation assembly. The heat dissipation assembly is configured to be immersed in a coolant in a tank and thermally coupled to a heat source. The heat dissipation assembly includes a heat exchange plate and a boiling enhancement structure. The heat exchange plate has a heat absorption surface, a heat dissipation surface and a coupling surface. The heat absorption surface is configured to be thermally coupled to the heat source, the heat dissipation surface faces away from the heat absorption surface, the coupling surface is located at a periphery of the heat dissipation surface, and the coupling surface is configured to be connected to a cover so as to form a fluid chamber. The boiling enhancement structure is located at the heat dissipation surface of the heat exchange plate and configured to be exposed to the coolant in the tank.

Another embodiment of the disclosure provides a motherboard module. The motherboard module is configured to be immersed in a coolant in a tank. The motherboard module includes a motherboard and a heat dissipation module. The motherboard has a heat source. The heat dissipation module includes a heat exchange plate and a boiling enhancement structure. The heat exchange plate has a heat absorption surface, a heat dissipation surface and a coupling surface, the heat absorption surface is thermally coupled to the heat source, the heat dissipation surface faces away from the heat absorption surface, the coupling surface is located at a periphery of the heat dissipation surface, and the coupling surface is configured to be connected to a cover so as to form a fluid chamber. The boiling enhancement structure is located at the heat dissipation surface of the heat exchange plate and configured to be exposed to the coolant in the tank.

Still another embodiment of the disclosure provides a heat dissipation assembly. The heat dissipation assembly is configured to be selectively immersed in a coolant in a tank and thermally coupled to a heat source. The heat dissipation assembly includes a heat exchange plate, a boiling enhancement structure, a cover, an inlet joint and at least one outlet joint. The heat exchange plate has a heat absorption surface and a heat dissipation surface, the heat absorption surface is configured to be thermally coupled to the heat source, and the heat dissipation surface faces away from the heat absorption surface. The boiling enhancement structure is disposed on the heat dissipation surface. The cover is coupled to the heat exchange plate and covers the boiling enhancement structure, and the cover and the heat exchange plate together form a fluid chamber. The inlet joint is connected to the cover. The outlet joint is connected to the cover. The inlet joint, the outlet joint or the cover is removable from the heat exchange plate so as to expose the boiling enhancement structure to the coolant in the tank.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 shows a side view of a motherboard module of some embodiment of the disclosure;

FIG. 2 shows an exploded view of a heat dissipation assembly of some embodiment of the disclosure;

FIG. 3 shows a cross-sectional view of a motherboard module of some embodiment of the disclosure;

FIG. 4 shows a bottom view of a cover of a heat dissipation assembly of some embodiment of the disclosure;

FIG. 5 shows a cross-sectional view of a heat dissipation assembly of some embodiment of the disclosure when the heat dissipation assembly is in a boiler plate mode;

FIG. 6 shows a cross-sectional view of a motherboard module of some embodiment of the disclosure; and

FIG. 7 shows a cross-sectional view of a heat dissipation assembly of some embodiment of the disclosure when the heat dissipation assembly is in a boiler plate mode.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

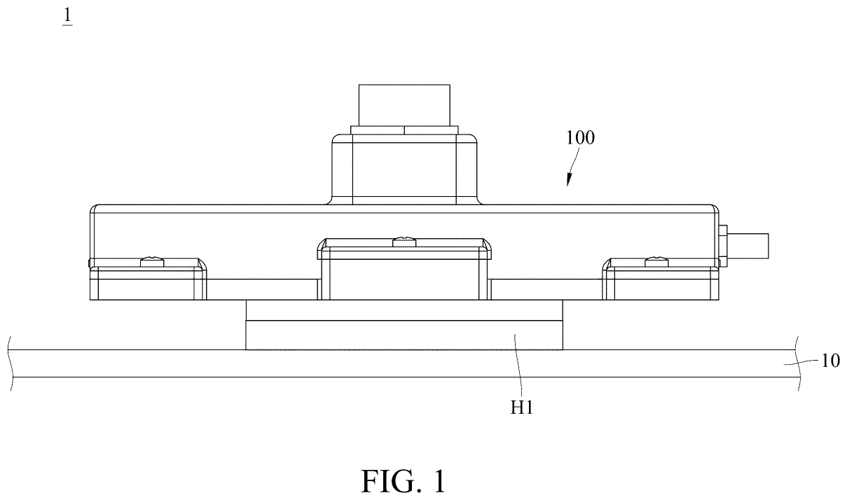

Referring to FIG. 1, FIG. 1 shows a side view of a motherboard module 1 of some embodiment of the disclosure. The structural arrangement shown in FIG. 1 can be applied to other embodiments of the disclosure.

In this embodiment, the motherboard module 1 includes a motherboard 10 and a heat dissipation assembly 100. The motherboard 10 has a heat source H1. The heat source H1 is, for example, a GPU or a CPU. The heat dissipation assembly 100 is thermally coupled to the heat source H1 of the motherboard 10. The following paragraphs will exemplarily introduce the heat dissipation assembly 100.

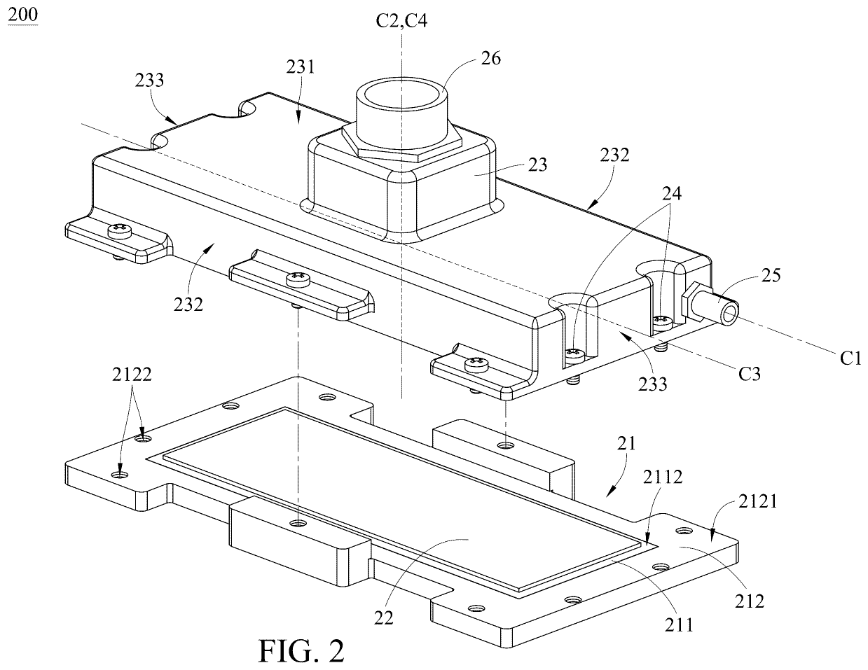

Referring to FIG. 2, FIG. 2 shows an exploded view of a heat dissipation assembly 200 of some embodiment of the disclosure. The structural arrangement shown in FIG. 2 can be applied to other embodiments of the disclosure. The heat dissipation assembly 200 includes a heat exchange plate 21 and a boiling enhancement structure 22. In addition, the heat dissipation assembly 200 may further include a cover 23, a plurality of fasteners 24, an inlet joint 25 and an outlet joint 26.

The heat exchange plate 21 includes a heat exchange portion 211 and a frame portion 212, and the frame portion 212 surrounds the heat exchange portion 211 and is fixed to the heat exchange portion 211. The frame portion 212 has a coupling surface 2121 and a plurality of fastening holes 2122. The coupling surface 2121 and a heat dissipation surface 2112 of the heat exchange portion 211 face a same direction. The fastening holes 2122 are, for example, screw holes, and the fastening holes 2122 are located at the coupling surface 2121 and are spaced apart from one another. In some embodiments, the heat exchange portion is, for example, made of copper. In some embodiments, the heat exchange portion is, for example, a vapor chamber. In some embodiments, the frame portion is, for example, made of aluminum.

Note that the heat exchange plate 21 is not restricted to being formed by two separate pieces (e.g., the heat exchange portion 211 and the frame portion 212). In some other embodiments, the heat exchange plate 21 may be formed by a single piece. For example, the entire heat exchange plate 21 may be a vapor chamber.

The boiling enhancement structure 22 is located at the heat dissipation surface 2112 of the heat exchange portion 211 of the heat exchange plate 21 and is configured to contact a coolant (not shown). The boiling enhancement structure is to increase bubble nucleation sites, produce more boiling bubbles per unit time and increase the contact area with the coolant. Although the boiling enhancement structure shown in FIG. 2 is simplified to a sheet, the boiling enhancement structure referred in the disclosure may actually include at least one of metal mesh structure, sheet-shaped fin structure, pin fin structure or sintered metal structure.

The fasteners 24 are, for example, screws. The fasteners 24 are assembled with (e.g., penetrate through) the cover 23 and are screwed into the fastening holes 2122 of the frame portion 212 of the heat exchange plate 21, such that the cover 23 is removably coupled to the coupling surface 2121 of the frame portion 212. The cover 23 and the heat exchange plate 21 together form a fluid chamber (not shown), and the cover 23 covers the boiling enhancement structure 22 on the heat exchange portion 211 of the heat exchange plate 21.

The shape of the cover may be designed according to actual requirements. For example, in the embodiment of FIG. 2, the cover 23 is substantially a rectangular cover. The cover 23 has an outer top surface 231, two outer long side surfaces 232 and two outer short side surfaces 233. The two outer long side surfaces 232 and the two outer short side surfaces 233 are respectively located at different sides of a periphery of the outer top surface 231. The two outer long side surfaces 232 are located opposite to each other, and the two outer short side surfaces 233 are located opposite to each other.

The cover is connected to the inlet joint and the outlet joint. For example, in the embodiment of FIG. 2, the inlet joint 25 is connected to one of the outer short side surfaces 233 of the cover 23, and the outlet joint 26 is connected to the outer top surface 231 of the cover 23.

In some embodiment, a central line of the inlet joint does not pass through a central line of the outlet joint. In the embodiment of FIG. 2, a central line C3 of the outer short side surface 233 of the cover 23 intersects a central line C4 of the outer top surface 231, a central line C1 of the inlet joint 25 is offset from the central line C3 of the outer short side surface 233 of the cover 23, and a central line C2 of the outlet joint 26 is overlapped with the central line C4 of the outer top surface 231 of the cover 23, such that the central line C1 of the inlet joint 25 does not pass through the central line C2 of the outlet joint 26.

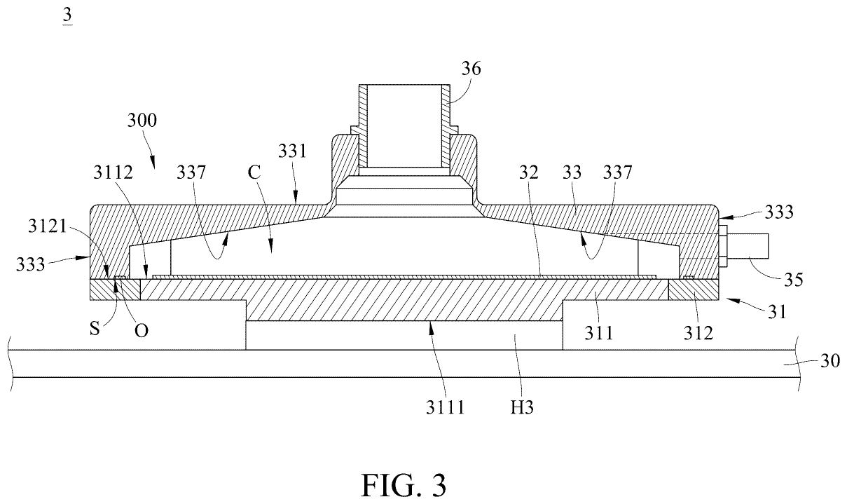

Referring to FIG. 3, FIG. 3 shows a cross-sectional view of a motherboard module 3 of some embodiment of the disclosure. The structural arrangement shown in FIG. 3 can be applied to other embodiments of the disclosure. A heat exchange plate 31 of a heat dissipation assembly 300 includes a heat exchange portion 311 and a frame portion 312. The frame portion 312 surrounds the heat exchange portion 311 and is fixed to the heat exchange portion 311. The frame portion 312 has a coupling surface 3121. The heat exchange portion 311 has a heat absorption surface 3111 and a heat dissipation surface 3112 facing away from the heat absorption surface 3111, and the heat absorption surface 3111 of the heat exchange portion 311 is thermally coupled to a heat source H3 of a motherboard 30. A boiling enhancement structure 32 is located at the heat dissipation surface 3112 and is surrounded by the coupling surface 3121 of the frame portion 312. When a cover 33 is sealingly coupled to the coupling surface 3121, the boiling enhancement structure 32 is exposed in a fluid chamber C. In some embodiments, the heat dissipation assembly 300 further includes a sealing ring O, and the cover 33 has an accommodation recess S. The sealing ring O is disposed in the accommodation recess S of the cover 33 and is clamped between the cover 33 and the coupling surface 3121, which achieves the sealing between the cover 33 and the coupling surface 3121. In some embodiments, the accommodation recess and the sealing ring may be disposed at the coupling surface of the heat exchange plate.

An outer top surface 331, two outer long side surfaces (e.g., the outer long side surfaces 232 shown in FIG. 2) and two outer short side surfaces 333 of the cover 33 face away from the fluid chamber C. The cover 33 further comprises a plurality of bubble guiding surfaces 337. The bubble guiding surfaces 337 are, for example, inclined surfaces. The bubble guiding surfaces 337 are respectively located at corners of the fluid chamber C located away from the heat exchange plate 31. On the other hand, the bubble guiding surfaces 337 are inclined surfaces that face a central line (e.g., the central line C2 shown in FIG. 2) of an outlet joint 36. In other words, the bubble guiding surfaces 337 extend along a direction towards the outlet joint 36. In some embodiments of the disclosure, the bubble guiding surfaces are configured to define a part of the fluid chamber, and highest positions of the bubble guiding surfaces are located adjacent to the outlet joint, which can guide bubbles in the fluid chamber towards the outlet joint. Taking FIG. 3 for example, the bubble guiding surfaces 337 gradually rise from a periphery of the fluid chamber C towards a position where the outlet joint 36 is located (e.g., a central area of the cover 33).

An inlet joint 35 of the heat dissipation assembly 300 shown in FIG. 3 is connected to one of the outer short side surfaces 333 of the cover 33, the outlet joint 36 is connected to the outer top surface 331 of the cover 33, and a central line of the inlet joint 35 (e.g., the central line C1 shown in FIG. 2) does not pass through a central line of the outlet joint 36 (e.g., the central line C2 shown in FIG. 2).

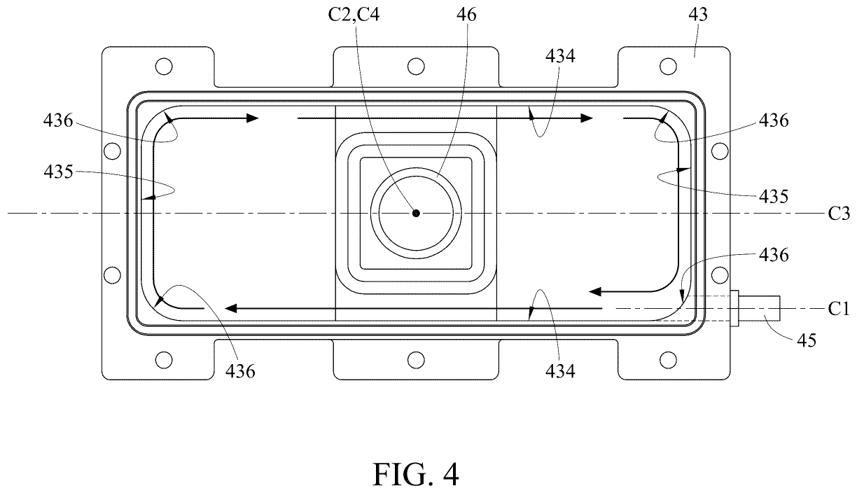

Referring to FIG. 4, FIG. 4 shows a bottom view of a cover of a heat dissipation assembly of some embodiment of the disclosure. The structural arrangement shown in FIG. 4 can be applied to other embodiments of the disclosure. A cover 43 shown in FIG. 4 has two inner long side surfaces 434, two inner short side surfaces 435 and a plurality of flow guiding surfaces 436 surrounding the fluid chamber (e.g., the fluid chamber C shown in FIG. 3). The flow guiding surfaces 436 are, for example, curved surfaces, and the flow guiding surfaces 436 are configured to guide the coolant entering into the fluid chamber.

Note that the flow guiding surfaces 436 are optional structures and may be omitted in some other embodiments.

In FIG. 4, the two inner long side surfaces 434 and the two inner short side surfaces 435 respectively face away from two outer long side surfaces (e.g., the outer long side surfaces 232 shown in FIG. 2) and two outer short side surfaces (e.g., the outer short side surfaces 233 shown in FIG. 2), and the two inner long side surfaces 434 and the two inner short side surfaces 435 are connected to one another via the flow guiding surfaces 436.

In FIG. 4, a central line C1 of an inlet joint 45 does not pass through a central line C2 of an outlet joint 46. For example, a central line C3 of the outer short side surface of the cover 43 intersects a central line C4 of the outer top surface (e.g., the outer top surface 231 shown in FIG. 2), the central line C1 of the inlet joint 45 is offset from the central line C3 of the outer short side surface of the cover 43, and the central line C2 of the outlet joint 46 is overlapped with the central line C4 of the outer top surface of the cover 43, such that the central line C1 of the inlet joint 45 does not pass through the central line C2 of the outlet joint 46.

In the aforementioned embodiments, in a condition that the inlet joint and the outlet joint are connected to the cover, and the cover is assembled with the heat exchange plate, the heat dissipation assembly is in a cold plate mode. At this moment, the heat dissipation assembly and the motherboard are, for example, tested in an air environment, and the inlet joint and the outlet joint may be connected to pipes (not shown), such that the coolant can enter into the fluid chamber from the inlet joint to absorb heat conducted to the heat exchange portion of the heat exchange plate and the boiling enhancement structure from the heat source.

In the aforementioned embodiments, such as the embodiment of FIG. 2, the central line C1 of the inlet joint 25 does not pass through the central line C2 of the outlet joint 26, which can reduce the secondary flow in the fluid chamber C for reducing the pressure drop. In addition, the coolant can form a vortex in the fluid chamber C to concentrate the bubbles produced after the coolant absorbs heat towards the outlet joint 26. Note that when there are other structures can reduce the secondary flow in the fluid chamber, the central line of the inlet joint may pass through the central line of the outlet joint in some other embodiments.

In the aforementioned embodiments, such as the embodiment of FIG. 3, the bubble guiding surfaces 337 are inclined surfaces that face the central line C2 of the outlet joint 36, which can guide the bubbles produced after the coolant absorbs heat to the outlet joint 36 for preventing the bubbles from accumulating in the fluid chamber C and reducing the heat exchange efficiency. Note that when there are other structures can prevent the accumulation of the bubbles in the fluid chamber, the cover may not have the bubble guiding surfaces in some other embodiments.

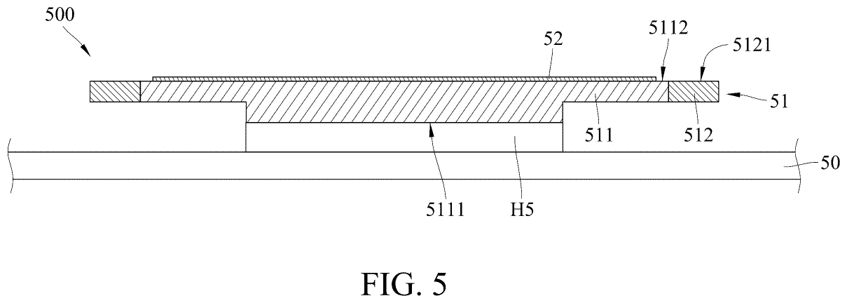

Then, referring to FIG. 5, FIG. 5 shows a cross-sectional view of a heat dissipation assembly 500 of some embodiment of the disclosure when the heat dissipation assembly is in a boiler plate mode. The structural arrangement shown in FIG. 5 can be applied to other embodiments of the disclosure.

In this embodiment, the heat dissipation assembly 500 can be switched from a cold plate mode to a boiler plate mode. For example, in a condition that a heat exchange plate 51 is maintained to be thermally coupled to a heat source H5 of a motherboard 50, the cover (e.g., the cover 33 shown in FIG. 3) can be removed from the heat exchange plate 51, such that the heat dissipation assembly 500 is in the boiler plate mode. The heat exchange plate 51 includes a heat exchange portion 511 and a frame portion 512. The frame portion 512 surrounds the heat exchange portion 511 and is fixed to the heat exchange portion 511. The frame portion 512 has a coupling surface 5121. The heat exchange portion 511 has a heat absorption surface 5111 and a heat dissipation surface 5112 facing away from the heat absorption surface 5111, and the heat absorption surface 5111 of the heat exchange portion 511 is thermally coupled to the heat source H5 of the motherboard 50. A boiling enhancement structure 52 is located at the heat dissipation surface 5112 of the heat exchange portion 511 of the heat exchange plate 51 and is configured to contact a coolant (not shown). The heat dissipation assembly 500 in the boiler plate mode is configured to be immersed in the coolant in a tank (not shown) along with the motherboard 50 during the test or normal operation of the motherboard 50. At this moment, the boiling enhancement structure 52 on the heat exchange plate 51 is configured to be exposed to the coolant in the tank. It can be understood from the above that, during the switching between aforementioned modes in the test of the heat source H5, the heat exchange plate 51 is not removed from the heat source H5, thereby reducing the complexity of the test.

In this embodiment, the switching from the cold plate mode to the boiler plate mode of the heat dissipation assembly 500 is not restricted to being achieved by removing the cover 33 and may be achieved by removing the inlet joint and the outlet joint on the cover. In such a case, when the heat dissipation assembly in the boiler plate mode and the motherboard are immersed in the coolant in the tank together, the coolant can flow into the fluid chamber from holes of the cover for the installations of the inlet joint and the outlet joint, such that the boiling enhancement structure is exposed to the coolant.

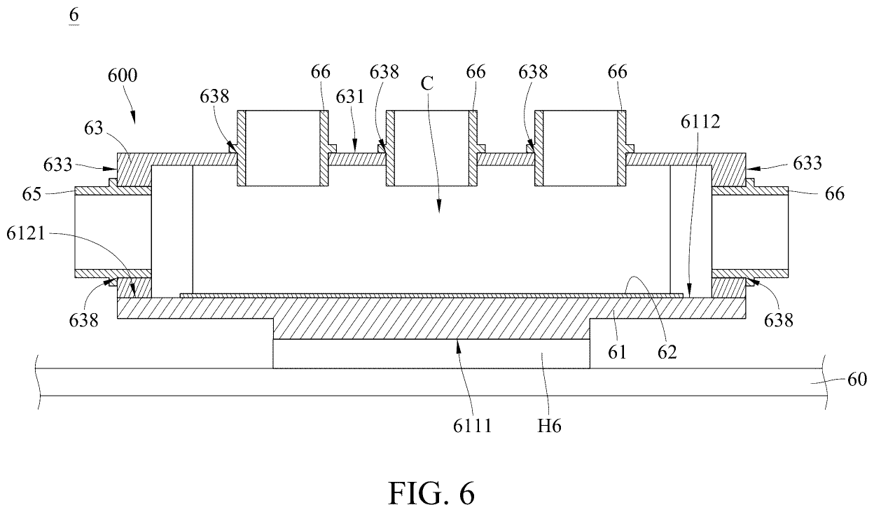

Then, referring to FIG. 6, FIG. 6 shows a cross-sectional view of a motherboard module 6 of some embodiment of the disclosure. The structural arrangement shown in FIG. 6 can be applied to other embodiments of the disclosure.

In this embodiment, a heat exchange plate 61 is, for example, formed by a single piece. For example, the entire heat exchange plate 61 is a vapor chamber. A heat absorption surface 6111 and a heat dissipation surface 6112 of the heat exchange plate 61 are respectively located at two opposite sides of the heat exchange plate 61, and a coupling surface 6121 of the heat exchange plate 61 surrounds the heat dissipation surface 6112. The heat absorption surface 6111 of the heat exchange plate 61 is thermally coupled to a heat source H6 of a motherboard 60. A boiling enhancement structure 62 is located at the heat dissipation surface 6112 of the heat exchange plate 61 and is configured to contact a coolant (not shown).

A cover 63 is irremovably coupled to the coupling surface 6121 of the heat exchange plate 61. In other words, when the cover 63 is forced to be separated from the heat exchange plate 61, the cover 63 and the heat exchange plate 61 may be damaged. For example, the cover 63 may be integrally coupled to the coupling surface 6121 of the heat exchange plate 61, or the cover 63 may be coupled to the coupling surface 6121 of the heat exchange plate 61 via a welding manner.

In this embodiment, the cover 63 has a plurality of joint installation holes 638, where two of the joint installation holes 638 are, for example, located at two opposite outer short side surfaces 633 of the cover 63, and the other of the joint installation holes 638 are, for example, located at an outer top surface 631 of the cover 63. In addition, the heat dissipation assembly 600 includes an inlet joint 65 and a plurality of outlet joints 66. The inlet joint 65 and the outlet joints 66 are respectively removably installed in the joint installation holes 638 of the cover 63.

In this embodiment, in a condition that the inlet joint 65 and the outlet joints 66 are installed on the cover 63, the heat dissipation assembly 600 is in a cold plate mode. At this moment, the heat dissipation assembly 600 and the motherboard 60 are, for example, tested in an air environment, and the inlet joint 65 and the outlet joints 66 may be connected to pipes (not shown), such that the coolant can enter into the fluid chamber C from the inlet joint 65 to absorb heat conducted to the heat exchange plate 61 and the boiling enhancement structure 62 from the heat source H6.

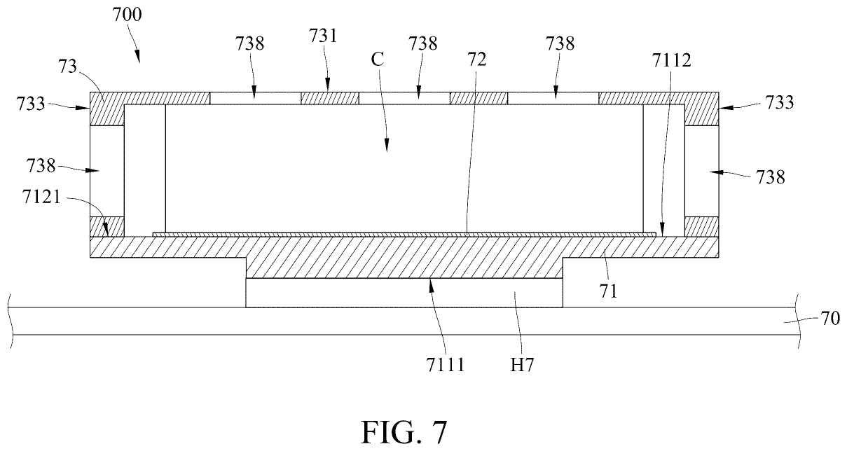

Then, referring to FIG. 7, FIG. 7 shows a cross-sectional view of a heat dissipation assembly 700 of some embodiment of the disclosure when the heat dissipation assembly 700 is in a boiler plate mode. The structural arrangement shown in FIG. 7 can be applied to other embodiments of the disclosure.

In this embodiment, the heat dissipation assembly 700 may be switched from a cold plate mode to a boiler plate mode. For example, in a condition that a heat exchange plate 71 is maintained to be thermally coupled to a heat source H7 of a motherboard 70, an inlet joint (e.g., the inlet joint 65 shown in FIG. 6) and outlet joints (e.g., the outlet joints 66 shown in FIG. 6) can be removed from the cover 73, such that the heat dissipation assembly 700 is in the boiler plate mode. A heat absorption surface 7111 and a heat dissipation surface 7112 of the heat exchange plate 71 are respectively located at two opposite sides of the heat exchange plate 71, and a coupling surface 7121 of the heat exchange plate 71 surrounds the heat dissipation surface 7112. The heat absorption surface 7111 of the heat exchange plate 71 is thermally coupled to the heat source H7 of the motherboard 70. A boiling enhancement structure 72 is located at the heat dissipation surface 7112 of the heat exchange plate 71 and is configured to contact a coolant (not shown). A cover 73 has a plurality of joint installation holes 738, where two of the joint installation holes 738 are, for example, located at two opposite outer short side surfaces 733 of the cover 73, and the other of the joint installation holes 738 are, for example, located at an outer top surface 731 of the cover 73. The heat dissipation assembly 700 in the boiler plate mode is configured to be immersed in the coolant in a tank (not shown) along with the motherboard 70 during the test or normal operation of the motherboard 70, such that the coolant enters into a fluid chamber C from the joint installation holes 738 for exposing the boiling enhancement structure 52 to the coolant in the tank. It can be understood from the above that, during the switching between aforementioned modes in the test of the heat source H7, the heat exchange plate 71 is not removed from the heat source H7, thereby reducing the complexity of the test.

According to the heat dissipation assemblies and the motherboard modules as discussed in the above embodiments, the cover is coupled to the heat exchange plate and covers the boiling enhancement structure, the cover and the heat exchange plate together form the fluid chamber, and the inlet joint and the outlet joint connected to the cover or the cover is removable from the heat exchange plate so as to expose the boiling enhancement structure to the coolant in the tank, which enables the heat dissipation assembly to have the cold plate mode and the boiler plate mode. The cold plate mode is that the cover is coupled to the heat exchange plate, and the inlet joint and the outlet joint are connected to the cover, such that the heat dissipation assembly can be served as a cold plate to be connected to pipes in the air environment. The boiler plate mode is that the cover is removed from the heat exchange plate, or the inlet joint and the outlet joint connected to the cover are removed from the cover, such that the heat dissipation assembly can be served as a boiler plate to be immersed in the coolant in the tank. During the switching between aforementioned modes in the test of the heat source, the heat exchange plate is not removed from the heat source, and the cover or the joints are components only to be removed, thereby reducing the complexity of the test.

In addition, the central line of the inlet joint does not pass through the central line of the outlet joint, which can reduce the secondary flow in the fluid chamber for reducing the pressure drop. Furthermore, the coolant can form a vortex in the fluid chamber to concentrate the bubbles produced after the coolant absorbs heat towards the outlet joint.

On the other hand, the bubble guiding surfaces are inclined surfaces and face the central line of the outlet joint, which can guide the bubbles produced after the coolant absorbs heat to the outlet joint for preventing the bubbles from accumulating in the fluid chamber and reducing the heat exchange efficiency.

Accordingly, one aspect of the disclosure provides a heat dissipation assembly, configured to be immersed in a coolant in a tank and thermally coupled to a heat source, the heat dissipation assembly including:
a heat exchange plate, having a heat absorption surface, a heat dissipation surface and a coupling surface, wherein the heat absorption surface is configured to be thermally coupled to the heat source, the heat dissipation surface faces away from the heat absorption surface, the coupling surface is located at a periphery of the heat dissipation surface, and the coupling surface is configured to be connected to a cover so as to form a fluid chamber; and
a boiling enhancement structure, located at the heat dissipation surface of the heat exchange plate and configured to be exposed to the coolant in the tank.

In some embodiments, the heat exchange plate includes a frame portion and a heat exchange portion, the frame portion surrounds the heat exchange portion, the heat absorption surface and the heat dissipation surface are respectively located at two opposite sides of the heat exchange portion, and the coupling surface is located at the frame portion.

In some embodiments, the frame portion and the cover are made of aluminum, and the heat exchange portion is made of copper.

In some embodiments, at least part of the heat exchange plate is a vapor chamber.

In some embodiments, the heat exchange plate has a plurality of screw holes, the screw holes are disposed on the coupling surface and are spaced apart from each other, and the screw holes are configured for a plurality of screws assembled with the cover to be screwed thereinto.

In some embodiments, the coupling surface of the heat exchange plate is configured to be coupled to the cover in a welding manner.

One aspect of the disclosure provides a motherboard module, configured to be immersed in a coolant in a tank, the motherboard module including:
a motherboard, having a heat source; and
a heat dissipation module, including:
a heat exchange plate, having a heat absorption surface, a heat dissipation surface and a coupling surface, wherein the heat absorption surface is thermally coupled to the heat source, the heat dissipation surface faces away from the heat absorption surface, the coupling surface is located at a periphery of the heat dissipation surface, and the coupling surface is configured to be connected to a cover so as to form a fluid chamber; and
a boiling enhancement structure, located at the heat dissipation surface of the heat exchange plate and configured to be exposed to the coolant in the tank.

In some embodiment, the heat exchange plate includes a frame portion and a heat exchange portion, the frame portion surrounds the heat exchange portion, the heat absorption surface and the heat dissipation surface are respectively located at two opposite sides of the heat exchange portion, and the coupling surface is located at the frame portion.

In some embodiment, the frame portion and the cover are made of aluminum, and the heat exchange portion is made of copper.

In some embodiment, at least part of the heat exchange plate is a vapor chamber.

In some embodiment, the heat exchange plate has a plurality of screw holes, the screw holes are disposed on the coupling surface and are spaced apart from each other, and the screw holes are configured for a plurality of screws assembled with the cover to be screwed thereinto.

In some embodiment, the coupling surface of the heat exchange plate is configured to be coupled to the cover in a welding manner.

One aspect of the disclosure provides a heat dissipation assembly, configured to be selectively immersed in a coolant in a tank and thermally coupled to a heat source, the heat dissipation assembly including:
a heat exchange plate, having a heat absorption surface and a heat dissipation surface, wherein the heat absorption surface is configured to be thermally coupled to the heat source, and the heat dissipation surface faces away from the heat absorption surface;
a boiling enhancement structure, disposed on the heat dissipation surface;
a cover, coupled to the heat exchange plate and covering the boiling enhancement structure, wherein the cover and the heat exchange plate together form a fluid chamber;
an inlet joint, connected to the cover; and
at least one outlet joint, connected to the cover;
wherein the inlet joint, the outlet joint or the cover is removable from the heat exchange plate so as to expose the boiling enhancement structure to the coolant in the tank.

In some embodiments, the cover is removably coupled to the heat exchange plate.

In some embodiments, the cover is irremovably coupled to the heat exchange plate, and the inlet joint and the outlet joint are removably connected to the cover.

In some embodiments, the cover has an outer top surface, two outer long side surfaces and two outer short side surfaces, the two outer long side surfaces and the two outer short side surfaces are respectively located at different sides of a periphery of the outer top surface, the two outer long side surfaces are located opposite to each other, the two outer short side surfaces are located opposite to each other, the inlet joint is connected to one of the two outer short side surfaces of the cover, and the outlet joint is connected to the outer top surface of the cover.

In some embodiments, a central line of the inlet joint does not pass through a central line of the outlet joint.

In some embodiments, the cover further has two inner long side surfaces, two inner short side surfaces and a plurality of flow guiding surfaces, the two inner long side surfaces and the two inner short side surfaces respectively face away from the two outer long side surfaces and the two outer short side surfaces, and the two inner long side surfaces and the two inner short side surfaces are connected to one another via the flow guiding surfaces.

In some embodiments, the cover has a plurality of bubble guiding surfaces, the bubble guiding surfaces are respectively located at corners of the fluid chamber located away from the heat exchange plate.

In some embodiments, the bubble guiding surfaces are inclined surfaces and face a central line of the outlet joint.

In some embodiments, the cover has a plurality of bubble guiding surfaces, the bubble guiding surfaces are configured to define a part of the fluid chamber, and highest positions of the bubble guiding surfaces are located adjacent to the outlet joint.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A heat dissipation assembly, configured to be immersed in a coolant in a tank and thermally coupled to a heat source, the heat dissipation assembly comprising:
a heat exchange plate, having a heat absorption surface, a heat dissipation surface and a coupling surface, wherein the heat absorption surface is configured to be thermally coupled to the heat source, the heat dissipation surface faces away from the heat absorption surface, the coupling surface is located at a periphery of the heat dissipation surface, and the coupling surface is configured to be connected to a cover so as to form a fluid chamber; and
a boiling enhancement structure, located at the heat dissipation surface of the heat exchange plate and configured to be exposed to the coolant in the tank.

2. The heat dissipation assembly according to claim 1, wherein the heat exchange plate comprises a frame portion and a heat exchange portion, the frame portion surrounds the heat exchange portion, the heat absorption surface and the heat dissipation surface are respectively located at two opposite sides of the heat exchange portion, and the coupling surface is located at the frame portion.

3. The heat dissipation assembly according to claim 2, wherein the frame portion and the cover are made of aluminum, and the heat exchange portion is made of copper.

4. The heat dissipation assembly according to claim 1, wherein at least part of the heat exchange plate is a vapor chamber.

5. The heat dissipation assembly according to claim 1, wherein the heat exchange plate has a plurality of screw holes, the plurality of screw holes are disposed on the coupling surface and are spaced apart from each other, and the plurality of screw holes are configured for a plurality of screws assembled with the cover to be screwed thereinto.

6. The heat dissipation assembly according to claim 1, wherein the coupling surface of the heat exchange plate is configured to be coupled to the cover in a welding manner.

7. A motherboard module, configured to be immersed in a coolant in a tank, the motherboard module comprising:
a motherboard, having a heat source; and
a heat dissipation module, comprising:
a heat exchange plate, having a heat absorption surface, a heat dissipation surface and a coupling surface, wherein the heat absorption surface is thermally coupled to the heat source, the heat dissipation surface faces away from the heat absorption surface, the coupling surface is located at a periphery of the heat dissipation surface, and the coupling surface is configured to be connected to a cover so as to form a fluid chamber; and
a boiling enhancement structure, located at the heat dissipation surface of the heat exchange plate and configured to be exposed to the coolant in the tank.

8. The motherboard module according to claim 7, wherein the heat exchange plate comprises a frame portion and a heat exchange portion, the frame portion surrounds the heat exchange portion, the heat absorption surface and the heat dissipation surface are respectively located at two opposite sides of the heat exchange portion, and the coupling surface is located at the frame portion.

9. The motherboard module according to claim 8, wherein the frame portion and the cover are made of aluminum, and the heat exchange portion is made of copper.

10. The motherboard module according to claim 7, wherein at least part of the heat exchange plate is a vapor chamber.

11. The motherboard module according to claim 7, wherein the heat exchange plate has a plurality of screw holes, the plurality of screw holes are disposed on the coupling surface and are spaced apart from each other, and the plurality of screw holes are configured for a plurality of screws assembled with the cover to be screwed thereinto.

12. The motherboard module according to claim 7, wherein the coupling surface of the heat exchange plate is configured to be coupled to the cover in a welding manner.

13. A heat dissipation assembly, configured to be selectively immersed in a coolant in a tank and thermally coupled to a heat source, the heat dissipation assembly comprising:
a heat exchange plate, having a heat absorption surface and a heat dissipation surface, wherein the heat absorption surface is configured to be thermally coupled to the heat source, and the heat dissipation surface faces away from the heat absorption surface;
a boiling enhancement structure, disposed on the heat dissipation surface;
a cover, coupled to the heat exchange plate and covering the boiling enhancement structure, wherein the cover and the heat exchange plate together form a fluid chamber;
an inlet joint, connected to the cover; and
at least one outlet joint, connected to the cover;
wherein the inlet joint, the at least one outlet joint or the cover is removable from the heat exchange plate so as to expose the boiling enhancement structure to the coolant in the tank.

14. The heat dissipation assembly according to claim 13, wherein the cover is removably coupled to the heat exchange plate.

15. The heat dissipation assembly according to claim 13, wherein the cover is irremovably coupled to the heat exchange plate, and the inlet joint and the at least one outlet joint are removably connected to the cover.

16. The heat dissipation assembly according to claim 13, wherein the cover has an outer top surface, two outer long side surfaces and two outer short side surfaces, the two outer long side surfaces and the two outer short side surfaces are respectively located at different sides of a periphery of the outer top surface, the two outer long side surfaces are located opposite to each other, the two outer short side surfaces are located opposite to each other, the inlet joint is connected to one of the two outer short side surfaces of the cover, and the at least one outlet joint is connected to the outer top surface of the cover.

17. The heat dissipation assembly according to claim 16, wherein a central line of the inlet joint does not pass through a central line of the at least one outlet joint.

18. The heat dissipation assembly according to claim 16, wherein the cover further has two inner long side surfaces, two inner short side surfaces and a plurality of flow guiding surfaces, the two inner long side surfaces and the two inner short side surfaces respectively face away from the two outer long side surfaces and the two outer short side surfaces, and the two inner long side surfaces and the two inner short side surfaces are connected to one another via the plurality of flow guiding surfaces.

19. The heat dissipation assembly according to claim 13, wherein the cover has a plurality of bubble guiding surfaces, the plurality of bubble guiding surfaces are respectively located at corners of the fluid chamber located away from the heat exchange plate.

20. The heat dissipation assembly according to claim 19, wherein the plurality of bubble guiding surfaces are inclined surfaces and face a central line of the at least one outlet joint.

21. The heat dissipation assembly according to claim 13, wherein the cover has a plurality of bubble guiding surfaces, the plurality of bubble guiding surfaces are configured to define a part of the fluid chamber, and highest positions of the plurality of bubble guiding surfaces are located adjacent to the outlet joint.
